(19) United States
(12) Patent Application Publication
(10) Pub. No.: US 2023/0020162 A1
(43) Pub. Date: Jan. 19, 2023

(54) SEMICONDUCTOR DEVICE WITH METAL-INSULATOR-METAL (MIM) CAPACITOR AND MIM MANUFACTURING METHOD THEREOF

(71) Applicant: KEY FOUNDRY CO., LTD., Cheongju-si (KR)

(72) Inventors: Kwangho PARK, Cheongju-si (KR); Boseok OH, Cheongju-si (KR); Taekyun YOO, Cheongju-si (KR); Yoongyu HA, Cheongju-si (KR)

(73) Assignee: KEY FOUNDRY CO., LTD., Cheongju-si (KR)

(21) Appl. No.: 17/558,253

(22) Filed: Dec. 21, 2021

(30) Foreign Application Priority Data
Jul. 16, 2021 (KR) 10-2021-0093676

(51) Int. Cl. H01L 49/02

(52) U.S. Cl. CPC H01L 28/92; H01L 28/75

(57) ABSTRACT

A metal-insulator-metal (MIM) capacitor of a semiconductor device and a manufacturing method thereof are provided. The MIM capacitor includes: a first inter metal dielectric layer disposed on a substrate; a plurality of lower electrodes disposed on the first inter metal dielectric layer; a plurality of opening areas respectively disposed between the plurality of lower electrodes; a dielectric layer which covers the plurality of lower electrodes and the plurality of opening areas; and an upper electrode disposed on the dielectric layer. The dielectric layer is in contact with side surfaces and top surfaces of the plurality of lower electrodes. The dielectric layer is in direct contact with the first inter metal dielectric layer.

### CROSS-REFERENCE TO RELATED APPLICATION(S)

This application claims the benefit under 35 U.S.C. § 119 of Korean Patent Application No. 10-2021-0093676 filed on Jul. 16, 2021, in the Korean Intellectual Property Office, the entire disclosure of which is incorporated herein by reference for all purposes.

### BACKGROUND

### 1. Field

The following disclosure relates to a metal-insulator-metal (MIM) capacitor of a semiconductor device and a manufacturing method thereof.

### 2.Description of Related Art

The MIM capacitor may include a lower electrode, a dielectric layer, and an upper electrode, and most MIM capacitors may have a two-dimensional structure. Therefore, a value of the capacitance may depend only on a two-dimensional area. The MIM capacitor structure having such a two-dimensional structure has a limitation in increasing the capacitance.

### SUMMARY

This summary is provided to introduce a selection of concepts in a simplified form that are further described below in the Detailed Description. This summary is not intended to identify key features or essential features of the claimed subject matter, nor is it intended to be used as an aid in determining the scope of the claimed subject matter.

In a general aspect, metal-insulator-metal (MIM) capacitor includes a first inter metal dielectric layer formed on a substrate; a plurality of lower electrodes disposed on the first inter metal dielectric layer; a plurality of opening areas respectively disposed between the plurality of lower electrodes; a dielectric layer which covers the plurality of lower electrodes and the plurality of opening areas; and an upper electrode disposed on the dielectric layer, wherein the dielectric layer is in contact with side surfaces and top surfaces of the plurality of lower electrodes, and wherein the dielectric layer is in direct contact with the first inter metal dielectric layer.

The plurality of lower electrodes may be disposed to be connected to each other to form a network of electrodes.

The MIM capacitor may further include a plurality of first vias which may be disposed in the first inter metal dielectric layer, and are connected to the plurality of lower electrodes; a second inter metal dielectric layer disposed on the upper electrode; a plurality of second vias disposed in the second inter metal dielectric layer; and a metal wiring connected to the plurality of second vias.

The dielectric layer and the upper electrode may be sequentially disposed on the first inter metal dielectric layer.

Each of the plurality of lower electrodes may include a barrier metal, a metal layer, and a cap metal.

A barrier metal of one of the plurality of lower electrodes may be disposed to be spaced from a barrier metal of an adjacent lower electrode of the one of the plurality of lower electrodes.

The dielectric layer may be disposed in contact with a side surface of the barrier metal.

The plurality of opening areas may be respectively configured to have a same area.

Each of the plurality of lower electrodes may be configured to have one of a rectangular shape and a stripe shape.

The barrier metal, the dielectric layer, and the upper electrode may be sequentially disposed on the first inter metal dielectric layer.

The barrier metal of a first lower electrode is disposed to be connected to an adjacent barrier metal of a second lower electrode.

The dielectric layer may be disposed in direct contact with a top surface of the barrier metal.

In a general aspect, a metal-insulator-metal (MIM) capacitor manufacturing method includes forming a first inter metal dielectric layer on a substrate; forming a plurality of lower electrodes on the first inter metal dielectric layer; forming a dielectric layer to cover a top surface and side surfaces of each of the plurality of lower electrodes; and forming an upper electrode on the dielectric layer.

Each of the plurality of lower electrodes may include a barrier metal, a metal layer, and a cap metal.

The dielectric layer may cover side surfaces of the barrier metal, the metal layer, and the cap metal.

The plurality of lower electrodes may be connected to each other to form a network of electrodes.

The plurality of lower electrodes may include a barrier metal, a metal layer, and a cap metal, and the barrier metal of one of the plurality of lower electrodes is formed to be spaced from the barrier metal of an adjacent lower electrode of the one of the plurality of lower electrodes.

The method may include forming a plurality of first vias in the first inter metal dielectric layer; forming a second inter metal dielectric layer on the upper electrode; forming a plurality of second vias in the second inter metal dielectric layer; and forming a metal wiring connected to the plurality of second vias, wherein the plurality of first vias may be connected to the plurality of lower electrodes.

In a general aspect, a metal-insulator-metal (MIM) capacitor includes a first inter metal dielectric layer; a barrier metal, disposed on the first inter metal dielectric layer; a plurality of lower electrodes, disposed on the barrier metal; a plurality of open areas respectively disposed between each of the plurality of lower electrodes; a dielectric layer, disposed directly on the barrier metal, and further disposed on respective side surfaces and top surfaces of the plurality of lower electrodes; and an upper electrode, disposed on the dielectric layer.

The MIM capacitor may further include a second inter metal dielectric layer disposed on the upper electrode.

Other features and aspects will be apparent from the following detailed description, the drawings, and the claims.

### BRIEF DESCRIPTION OF DRAWINGS

FIGS. 1 to 3 illustrate example plan views of an example MIM capacitor, in accordance with one or more embodiments.

FIG. 4 illustrates an example cross sectional view taken along lines I-I′, II-II′, and III-III′ of FIGS. 1, 2, and 3.

FIG. 5 illustrates an example cross sectional view taken along line IV-IV′ of FIG. 3.

FIG. 6 illustrates an example structure of an example MIM capacitor, in accordance with one or more embodiments.

FIG. 7 illustrates an example structure of an example MIM capacitor, in accordance with one or more embodiments.

FIGS. 8A, 8B, 8C, and 9 to 14 illustrate example views of an example MIM capacitor manufacturing method, in accordance with one or more embodiments.

FIGS. 15 to 17 illustrate example views of an example MIM manufacturing method, in accordance with one or more embodiments.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of the application, may be omitted for increased clarity and conciseness.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms such as “above,” “upper,” “below,” and “lower” may be used herein for ease of description to describe one element's relationship to another element as shown in the figures. Such spatially relative terms are intended to encompass different orientations of the device in use or operation in addition to the orientation depicted in the figures. For example, if the device in the figures is turned over, an element described as being “above” or “upper” relative to another element will then be “below” or “lower” relative to the other element. Thus, the term “above” encompasses both the above and below orientations depending on the spatial orientation of the device. The device may also be oriented in other ways (for example, rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes shown in the drawings may occur. Thus, the examples described herein are not limited to the specific shapes shown in the drawings, but include varies in shape that occur during manufacturing.

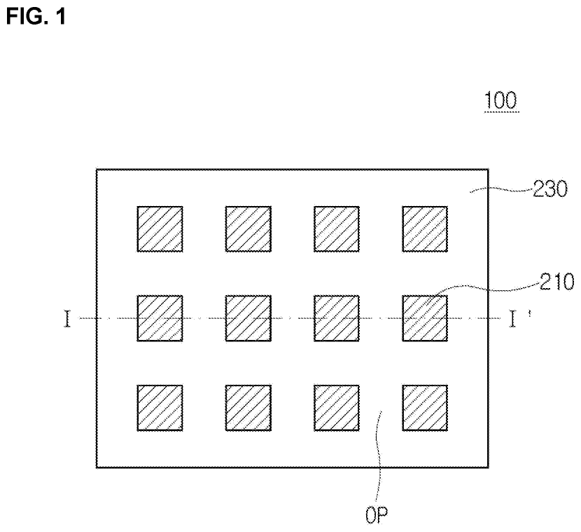

FIGS. 1 to 3 illustrate example plan views of an example MIM capacitor, in accordance with one or more embodiments.

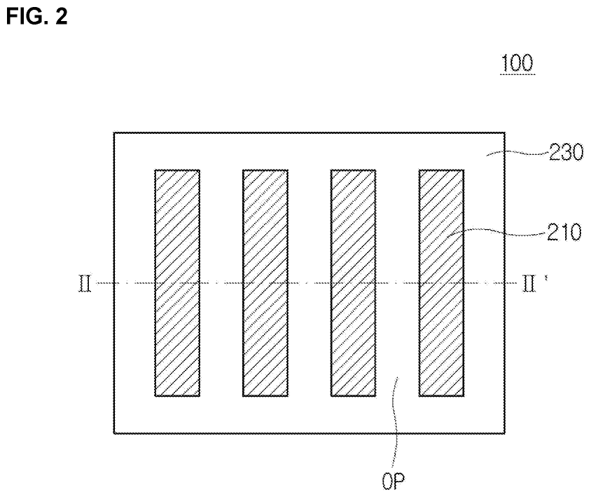

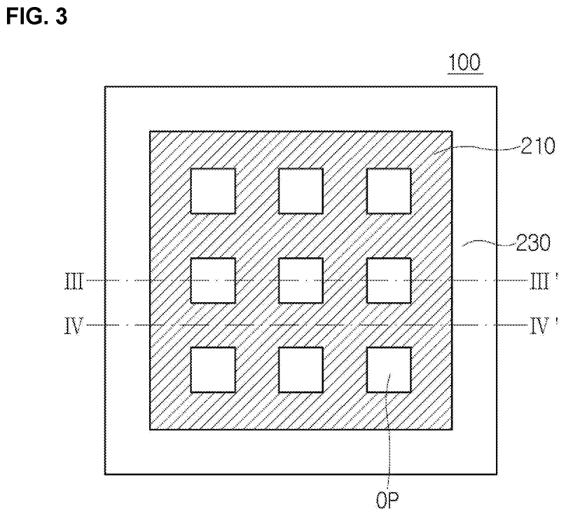

Referring to FIGS. 1 to 3, a metal-insulator-metal (MIM) capacitor 100 may include a plurality of lower electrodes 210, a dielectric layer (not shown), and a single upper electrode 230. In an example, the lower electrodes 210 may have various shapes. In an example, the plurality of lower electrodes 210 may have a rectangular shape, as illustrated in FIG. 1, a stripe shape, as illustrated in FIG. 2, and a mesh shape, as illustrated in FIG. 3. However, the shapes of the plurality of lower electrodes 210 are not limited thereto, and other shapes may be implemented. In an example, the upper electrode 230 may cover all the of the plurality of lower electrodes 210 in the form of one layer. The dielectric layer (not shown) may be formed between the plurality of lower electrodes 210 and the upper electrodes 230.

Herein, it is noted that use of the term “may” with respect to an example or embodiment, e.g., as to what an example or embodiment may include or implement, means that at least one example or embodiment exists where such a feature is included or implemented while all examples and embodiments are not limited thereto.

The one or more examples may implement a three-dimensional structure beyond a typical two-dimensional MIM structure in order to obtain a greater capacitance in the same area. Typically, capacitance is determined in a two-dimensional area where the lower electrode and the upper electrode meet. The total capacitance may be determined by how efficiently the layout of the lower electrode is made. Theoretically, it is possible to obtain more than twice the capacitance in the same area than the area of the existing MIM structure.

Specifically, the example MIM structure may be characterized in that it forms a three-dimensional MIM structure, and thus, may obtain more than twice the capacitance in the same area.

One or more examples provide an MIM capacitor of which a lower electrode has a three-dimensional structure. Since the lower electrode may have a surface area that is wider than a surface area of a typical MIM capacitor, the example MIM capacitor may have an improved capacitance, and may be able to obtain a greater capacitance in the same area than the area of the typical MIM capacitor.

Referring to FIGS. 1-3, a plurality of opening areas OP may be formed between the plurality of lower electrodes 210. As illustrated in FIG. 1, the upper electrode 230 may be formed in the opening area OP between the plurality of lower electrodes.

Referring to FIG. 3, as mentioned above, the plurality of lower electrodes 210 may have a network type or a mesh structure, and may be connected to each other. The plurality of lower electrodes 210 may have a mesh structure such that a plurality of opening areas OP may be formed between the lower electrodes 210. In an example, the plurality of opening areas may have a same area, respectively. The mesh structure may have the greatest capacitance.

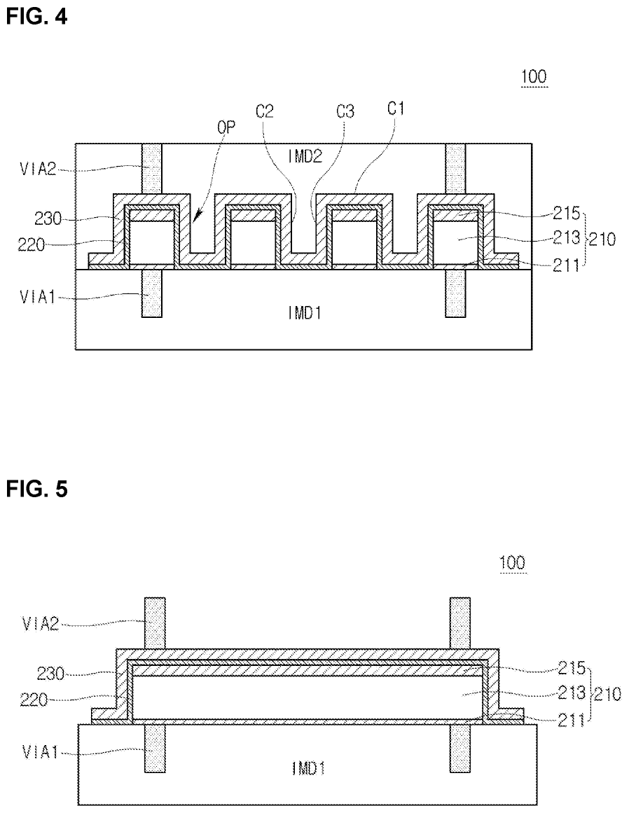

FIG. 4 illustrates an example cross sectional view taken along lines I-I′, II-II′, and III-III′of FIGS. 1, 2, and 3.

Referring to FIG. 4, the MIM capacitor 100 may include the lower electrode or electrodes 210, the dielectric layer 220 disposed on the lower electrode 210, and the upper electrode 230 disposed on the dielectric layer 220.

In a non-limiting example, the plurality of lower electrodes 210 may be formed of a multi-layered metal. In an example, the plurality of lower electrodes 210 may be formed of a triple layer of a barrier metal 211, a metal layer 213, and a cap metal 215. Any one of, but not limited to, Co, Ti, W, Ta, TiN, WN, TaN, and Ti/TiN stack layer may be used as the material of the barrier metal 211. Any one of, but not limited to, Al, Al—Cu, Cu, and W may be used as the material of the metal layer 211. A material of the cap metal 215 may be similar to a material of the barrier metal 211, and any one of, but not limited to, Co, Ti, W, Ta, TiN, WN, TaN, and Ti/TiN stack layer may be used as the material of the cap metal 215.

In an example, a same material as a material of the cap metal may be used to form the upper electrode 230. That is, any one of Co, Ti, W, Ta, TiN, WN, TaN, and Ti/TiN stack layers may be used as the material of the upper electrode 230. When TiN is used as the material of the upper electrode 230, the same material as the material of the barrier metal 215 included in the plurality of lower electrodes 210 may be formed.

In an example, SiO2 or SiN may be used as the material of the dielectric layer 220. Alternatively, any one or a combination of, but not limited to, HfO₂, Al₂O₃, Ta₂O₅, ZrO₂, etc., which are known as a high-k material, may be used as the dielectric layer 220. In an example, for a high capacitance, the HfO₂/Al₂O₃ may be used repeatedly.

The dielectric layer 220 may be interposed between the lower electrode 210 and the upper electrode 230. The dielectric layer 220 may also be deposited on the lower electrodes 210 in accordance with the unevenness of the plurality of lower electrodes 210, and may also be deposited on the side surface of the lower electrodes 210 with almost the same thickness. Since the dielectric layer 220 and the upper electrode 230 may be conformally formed along the curvature of the plurality of lower electrodes 210, the area serving as the capacitance includes not only the top surface of the lower electrodes 210, but also the side surfaces of the lower electrodes 210. Therefore, in the examples, the area of a sum of the two side surfaces C2 and C3 and the upper portion C1 which have a three-dimensional structure serves as a capacitance.

Additionally, as illustrated in FIG. 4, a first via VIA1 and a second via VIA2 may be formed. The first via VIA1 and the second via VIA2 may respectively be electrically connected to the lower electrode 210 and the upper electrode 230 of the MIM capacitor 100. The first via VIA1 and the second via VIA2 may be respectively formed in a first inter metal dielectric layer (hereinafter, referred to as IMD1) and a second inter metal dielectric layer (hereinafter, referred to as IMD2). In an example, SiO2, SiOF, SiOC, SiOCN, etc., may be used as the material of the first and second inter metal dielectric layers IMD1 and IMD2. Tungsten (VV) or copper (Cu) may be used as materials of the first and second via VIA1 and VIA2. Here, the first inter metal dielectric layer IMD1 is formed on a semiconductor substrate.

As illustrated in FIG. 4, the plurality of lower electrodes 210 may be patterned, so that the opening areas OP are formed between the respective lower electrodes 210. The first inter metal dielectric layer IMD1 may be disposed under the opening area OP. The dielectric layer 220 may be formed or disposed on the entire surface of the formed patterns of the plurality of lower electrodes 210. The dielectric layer 220 may also be formed or disposed to cover the side surfaces of each of the lower electrodes 210. Additionally, the upper electrode 230 may be formed or disposed to cover the top and side surfaces of the dielectric layer 220.

FIG. 5 illustrates an example cross sectional view taken along line IV-IV′ of FIG. 3.

Referring to FIG. 5, the plurality of lower electrodes 210 of FIG. 5 are formed long on the first inter metal dielectric layer IMD1. FIG. 5 illustrates that the plurality of lower electrodes may be connected to each other. The plurality of lower electrodes may have a mesh-type structures. Therefore, depending on which portion of the MIM capacitor is cut, as illustrated in FIG. 4, the plurality of lower electrodes may be disconnected from each other, and as illustrated in FIG. 5, the plurality of lower electrodes may be connected to each other. Since they are integrally connected to each other, there is an advantage that they can be easily electrically connected to each other.

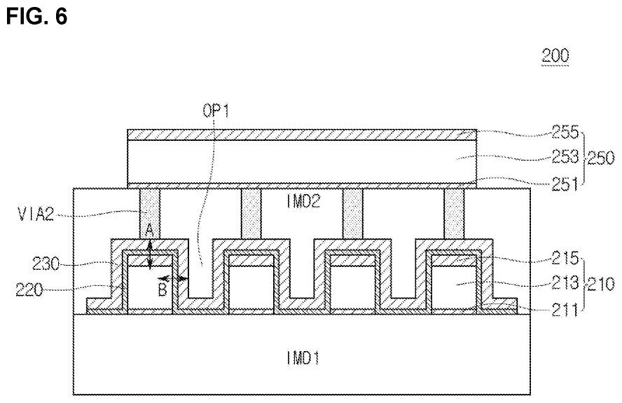

FIG. 6 illustrates an example structure of an example MIM capacitor, according to the embodiment of the present disclosure.

Referring to FIG. 6, an example MIM capacitor 200, in accordance with one or more embodiments, includes the first inter metal dielectric layer IMD1 formed or disposed on a semiconductor substrate; the plurality of lower electrodes 210 disposed on the first inter metal dielectric layer IMD1; the dielectric layer 220 disposed on the plurality of lower electrodes; and the upper electrode 230 disposed on the dielectric layer. In an example, each of the lower electrodes 210 includes the barrier metal 211, the metal layer 213, and the cap metal 215. In an example, the barrier metal 211 may be formed in each of the lower electrodes 210, and may be disconnected from an adjacent barrier metal 211. That is, a barrier metal 211 of a first lower electrode 211 may be formed to be spaced apart from a barrier metal 211 of an adjacent barrier metal 211. Therefore, the dielectric layer 220 may be formed in contact with a side surface of the disconnected barrier metal 211.

As illustrated in FIG. 6, in an opening area OP1, the dielectric layer 220 may be in direct contact with the first inter metal dielectric layer IMD1. Accordingly, the one dielectric layer and the one upper electrode may be sequentially formed on the first inter metal dielectric layer IMD1.

Additionally, the upper electrode 230 may be connected to an upper metal wiring 250 through the second via VIA2. In an example, a portion of the plurality of lower electrodes 210 may be formed together when a lower metal wiring (not shown) is formed.

As illustrated in FIG. 6, the structure of the MIM capacitor, in accordance with one or more embodiments, may be formed not only on a top surface “A” of the lower electrode, but also on a side surface “B” of the lower electrode. Therefore, the capacitance of the example MIM capacitor may obtain a greater capacitance in the same area than a capacitance of a typical MIM capacitor.

In an example, FIG. 6 illustrates a plurality of MIM capacitor structures which include the plurality of lower electrodes 210, the dielectric layer 220, and the upper electrode 230. The plurality of MIM capacitor structures 100 may be divided into a single MIM capacitor structure, respectively. That is, it is assumed that a unit capacitance is 1fF/um² for a single unit MIM capacitor composed of the one lower electrode 210, the dielectric layer 220, and the upper electrode 230. It is assumed that the width and height of each of the lower electrodes 210 and a distance (space) between the lower electrodes 210 are the same and equal to 1 μm. It is assumed that the entire length of the MIM capacitor structure is 15 μm and 11 μm in X and Y directions, respectively. The total capacitance of the typical capacitor structure and the total capacitance of the example mesh structure illustrated in FIG. 3 are calculated as 165 fF and 322 fF, respectively. The structure of the example MIM capacitor structure shows an approximately two-fold difference in capacity. Additionally, although the height of the lower electrode 210 is assumed to be the same as the width and space, the height of the lower electrode 210 is actually 1.5 times or more. Therefore, the structure of the example MIM capacitor structure can have 2.5 times or more capacitance than a capacitance of the typical capacitor structure.

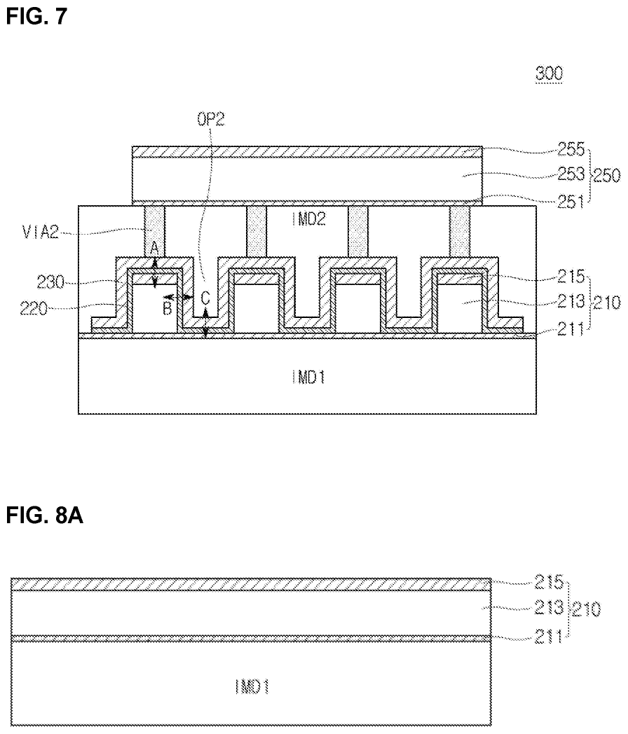

FIG. 7 illustrates an example structure of an example MIM capacitor, in accordance with one or more embodiments.

Referring to FIG. 7, an example MIM capacitor 300, in accordance with one or more embodiments includes the first inter metal dielectric layer IMD1 formed on a semiconductor substrate; the plurality of lower electrodes 210 formed on the first inter metal dielectric layer IMD1; the dielectric layer 220 disposed on the lower electrodes 210; and the upper electrode 230 disposed on the dielectric layer 220. In an example, each of the lower electrodes 210 includes the barrier metal 211, the metal layer 213, and the cap metal 215.

Unlike FIG. 6, as illustrated in FIG. 7, the barrier metal 211 may be formed in each of the lower electrodes 210, and may be connected to an adjacent barrier metal 211. Therefore, the barrier metals 211 may not be disconnected from each other, and may be continuously connected.

Therefore, the dielectric layer 220 may not be formed or disposed to be in contact with the side surface of the barrier metal 211, but may be formed or disposed in direct contact with a top surface of the barrier metal 211. Therefore, the example is characterized in that, in an opening area OP2, the dielectric layer 220 may not be in direct contact with the first inter metal dielectric layer IMD1. Accordingly, the barrier metal 211, the one dielectric layer 220, and the one upper electrode 230 may be sequentially formed on the first inter metal dielectric layer IMD1.

As illustrated in FIG. 7, the structure of the example MIM capacitor 300 may be formed not only on the top surface “A” and a side surface “B” of the lower electrode 210, but may also be formed on a bottom surface “C” of the opening area OP2. Additionally, in the opening area OP2, the dielectric layer 220 may not be in direct contact with the first inter metal dielectric layer IMD1, and the barrier metal 211 of the plurality of lower electrodes 210 is formed. Therefore, there is an advantage that additional capacitance can be obtained even in an up and down direction “C” of the opening area OP2. The capacitance of the example MIM capacitor may obtain a greater capacitance in the same area than a capacitance of a typical MIM capacitor.

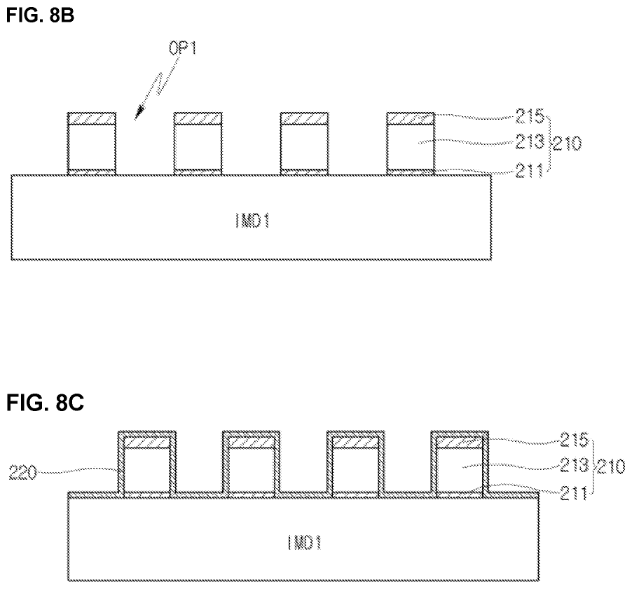

Hereinafter, a MIM capacitor manufacturing method, in accordance with one or more embodiments, will be described with reference to FIGS. 8A, 8B, 8C, and 9 to 14.

Referring to FIG. 8A, the first inter metal dielectric layer IMD1 may be formed on a semiconductor substrate having a MIM capacitor formation region. In a non-limiting example, SiO2, SiOF, SiOC, SiOCN, etc., may be implemented as the material of the first inter metal dielectric layer IMD1. A plurality of first vias VIA1 (not shown) may be formed in the first inter metal dielectric layer IMD1.

Referring to FIG. 8A, an operation of depositing the lower metal layer 210 corresponding to the lower electrode 210 in order to form the plurality of lower electrodes 210 on the first inter metal dielectric layer IMD1 is performed. The lower metal layer 210 may be formed together when a first metal wiring (not shown) is formed. The lower metal layer 210 may be formed of a multi-layered metal layer. In an example, the lower metal layer 210 may be formed of a triple layer of the barrier metal 211, the metal layer 213, and the cap metal 215. In a non-limiting example, Co, Ti, W, Ta, TiN, WN, TaN, Ti/TiN stack layer, etc., may be used as the material of the barrier metal 211. In a non-limiting example, Al, Al—Cu, Cu, and W may be used as the material of the metal layer 211. In a non-limiting example, Co, Ti, W, Ta, TiN, WN, TaN, and Ti/TiN stack layer may be used as the material of the cap metal 215.

Referring to FIG. 8B, an operation is illustrated in which the lower metal layer 210 is patterned in order to form the plurality of lower electrodes 210. The plurality of lower electrodes 210 may be formed by performing photolithography, exposure, and development on the lower metal layer 210 and by etching the lower metal layer 210. The plurality of lower electrodes 210 may be patterned such that a plurality of opening areas OP1 may be, as illustrated in FIG. 7, formed within the MIM capacitor formation region. The opening area OP1 exposes a surface of the first inter metal dielectric layer IMD1.

Referring to FIG. 8C, a dielectric layer deposition operation is illustrated in which the dielectric layer 220 is deposited on the plurality of lower electrodes 210. The dielectric layer 220 may be formed on the entire surface of the lower electrodes 210 which were formed based on the patterning of the plurality of lower electrodes 210. The dielectric layer 220 may also be formed to cover the side surfaces of the plurality of lower electrodes 210. As an example, SiO2 or SiN may be used as the material of the dielectric layer 220. Alternatively, any one or a combination of HfO₂, Al₂O₃, Ta₂O₅, ZrO₂, etc., which are known as a high-k material, may be used as the dielectric layer 220. In an example, for a high capacitance, the HfO₂/Al₂O₃ may be used repeatedly.

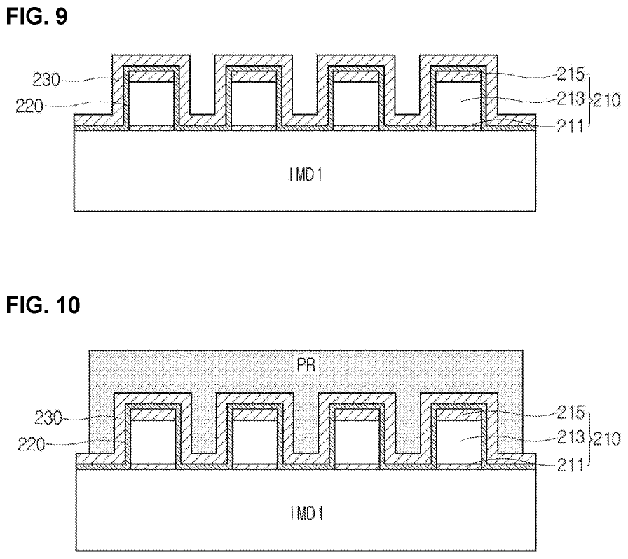

FIG. 9 illustrates an upper electrode 230 deposition operation of depositing the upper electrode 230 on the dielectric layer 220. The upper electrode 230 may be formed to cover not only the top surface of the dielectric layer 220, but also the side surfaces of the dielectric layer 220. Any one of, but not limited to, Co, Ti, W, Ta, TiN, WN, TaN, and Ti/TiN stack layers may be used as the material of the upper electrode 230. When TiN is used as the material of the upper electrode 230, the same material as that of TiN 215 of the plurality of lower electrodes 210 is formed.

FIG. 10 illustrates an operation of defining the MIM capacitor formation region by a photolithography process.

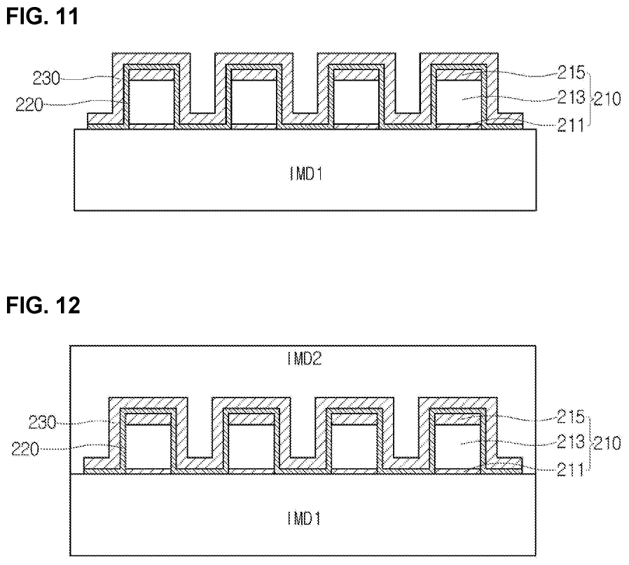

FIG. 11 illustrates an operation of etching the upper electrode 230 and the dielectric layer 220 in accordance with a photo pattern defined as the MIM capacitor formation region in FIG. 10.

FIG. 12 illustrates an operation of depositing the second inter metal dielectric layer IMD2 on the upper electrode 230. In an example, SiO2, SiOF, SiOC, SiOCN, etc., can be used as the material of the second inter metal dielectric layer IMD2.

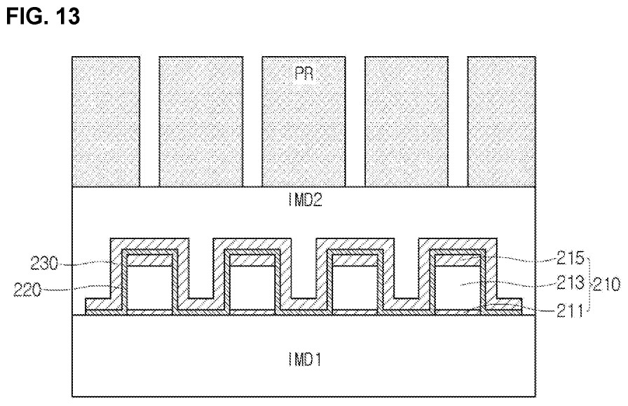

FIG. 13 illustrates an operation of defining the second via VIA2 formation region by a photolithography process. A photoresist material may be coated on the second inter metal dielectric layer IMD2, and a mask pattern PR that forms the second via VIA2 may be formed through exposure and development processes.

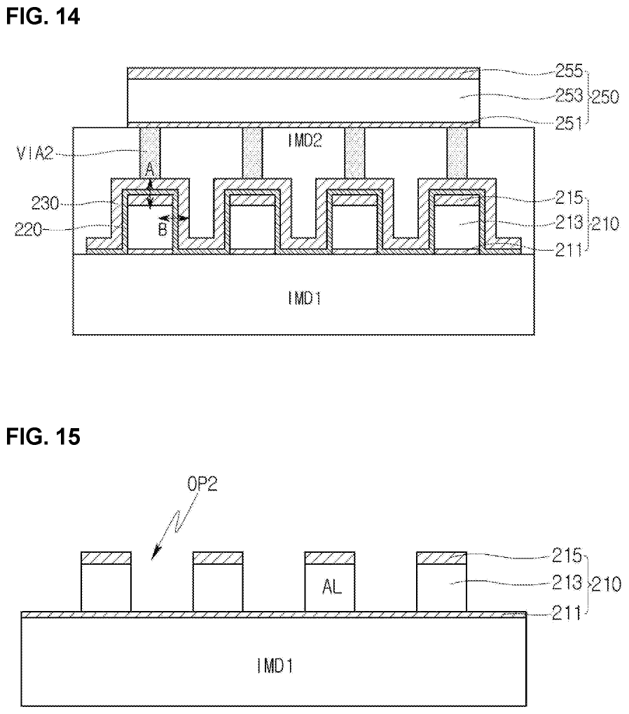

FIG. 14 illustrates that a via hole is formed by etching the second inter metal dielectric layer IMD2 by using the mask pattern PR, and the mask pattern PR is removed. Then, the second via VIA2 is formed by filling the via hole with a metal material. The second via VIA2 is formed in the second inter metal dielectric layer IMD2, and is electrically connected to the upper electrode 230. In an example, Tungsten (W) or copper (Cu) may be used as the material of the second via VIA2. However, the material is not limited thereto.

Still referring to FIG. 14, the upper metal wiring 250 is formed on the second via VIA2, and above the second inter metal dielectric layer IMD2. Therefore, the upper metal wiring 250 and the upper electrode 230 are connected through the second via VIA2. A material such as, but not limited to, Al, Al—Cu, Cu, W, etc., may be used as the material of the upper metal wiring 250. The upper metal wiring 250 may be formed of a multi-layered metal. In an example, the upper metal wiring 250 may be formed of a triple layer of a barrier metal 251, a metal layer 253, and a cap metal 255.

The example MIM capacitor described above is characterized in that it has a three-dimensional structure beyond the typical MIM capacitor formed in a two-dimensional planar structure. That is, the plurality of lower electrodes 210 include the opening area OP1, and the dielectric layer 220, disposed on the plurality of lower electrodes 210, may be deposited not only on the plurality of lower electrodes 210 in accordance with the unevenness of the plurality of lower electrodes 210, but may also be disposed on the side surfaces of the plurality of lower electrodes 210 in the same manner. Additionally, as with the dielectric layer 220, the upper electrode 230 may also be deposited, not only on the top surface of the dielectric layer 220, but also on the side surfaces of the dielectric layer 220. Accordingly, as illustrated in FIG. 14, the capacitance of the example MIM capacitor may be formed not only in an up and down direction “A” but also in a lateral direction “B”, so that it is possible to obtain a greater capacitance in the same area than the capacitance of a typical MIM capacitor. As illustrated in the example MIM capacitor manufacturing method illustrated in FIG. 14, the barrier metal 211 may be disposed directly on a top surface of the first inter metal dielectric layer IMD1. Additionally, a barrier metal layer 211 of a first lower electrode 210 may be spatially separated from a barrier metal layer 211 of an adjacent lower electrode 210.

Hereinafter, another example MIM capacitor manufacturing method, in accordance with one or more embodiments, will be described with reference to FIGS. 15 to 17.

The second example is different from the above-mentioned example with regard to the opening area OP2 formed in the plurality of lower electrodes 210. Specifically, the second example is characterized in that the barrier metal 211 of a first lower electrode 210 may be connected to an adjacent barrier metal 211 of a second or adjacent lower electrode 210.

FIG. 15 illustrates a lower electrode 210 patterning operation. The metal layer 213 and the cap metal 215 of the plurality of lower electrodes 210 are patterned until the surface of the barrier metal 211 is exposed. The barrier metal 211 serves as an etch stop layer. A plurality of opening areas OP2 may be formed between the respective lower electrodes 210.

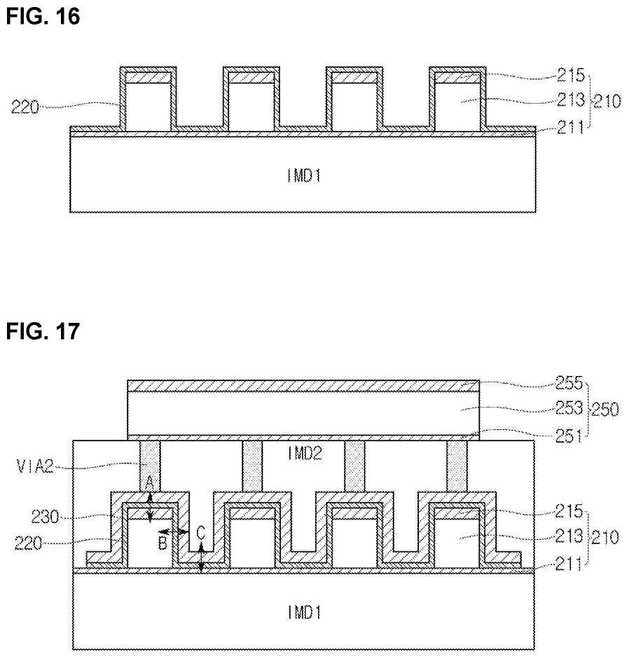

FIG. 16 illustrates an example operation of forming the dielectric layer 220 on the entire surface of the formed patterns of the plurality of lower electrodes 210. In the first example discussed above, the dielectric layer 220 may be in direct contact with the first inter metal dielectric layer IMD1 in the opening area OP1. However, in the second example illustrated in FIG. 17, the dielectric layer 220 may not be in direct contact with the first inter metal dielectric layer IMD1 even in the opening area OP2, since the dielectric layer 220 may be disposed on the barrier metal 211.

FIG. 17 illustrates an operation of connecting the upper metal wiring 250 and the upper electrode 230 through the second via VIA2.

As illustrated in FIG. 17, the example MIM capacitor according to the second example, may include the first inter metal dielectric layer IMD1 formed on a semiconductor substrate having a MIM capacitor formation region; the barrier metal 211 disposed on the first inter metal dielectric layer IMD1, the plurality of lower electrodes 210 formed of the metal layer 213 on the barrier metal 211 and of the cap metal 215 on the metal layer 213; the dielectric layer 220 disposed on the plurality of lower electrodes 210; and the upper electrode 230 disposed on the dielectric layer 220. Additionally, the metal layer 213 and the cap metal 215 may be patterned to form a plurality of opening areas OP2 which expose the surface of the barrier metal 211 in the MIM capacitor formation region.

While this disclosure includes specific examples, it will be apparent after an understanding of the disclosure of this application that various varies in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A metal-insulator-metal (MIM) capacitor, comprising:
a first inter metal dielectric layer formed on a substrate;
a plurality of lower electrodes disposed on the first inter metal dielectric layer;
a plurality of opening areas respectively disposed between the plurality of lower electrodes;
a dielectric layer which covers the plurality of lower electrodes and the plurality of opening areas; and
an upper electrode disposed on the dielectric layer,
wherein the dielectric layer is in contact with side surfaces and top surfaces of the plurality of lower electrodes, and
wherein the dielectric layer is in direct contact with the first inter metal dielectric layer.

2. The MIM capacitor of claim 1, wherein the plurality of lower electrodes are disposed to be connected to each other to form a network of electrodes.

3. The MIM capacitor of claim 1, further comprising:
a plurality of first vias which are disposed in the first inter metal dielectric layer, and are connected to the plurality of lower electrodes;
a second inter metal dielectric layer disposed on the upper electrode;
a plurality of second vias disposed in the second inter metal dielectric layer; and
a metal wiring connected to the plurality of second vias.

4. The MIM capacitor of claim 1, wherein the dielectric layer and the upper electrode are sequentially disposed on the first inter metal dielectric layer.

5. The MIM capacitor of claim 1, wherein each of the plurality of lower electrodes comprise a barrier metal, a metal layer, and a cap metal.

6. The MIM capacitor of claim 5, wherein a barrier metal of one of the plurality of lower electrodes is disposed to be spaced from a barrier metal of an adjacent lower electrode of the one of the plurality of lower electrodes.

7. The MIM capacitor of claim 5, wherein the dielectric layer is disposed in contact with a side surface of the barrier metal.

8. The MIM capacitor of claim 1, wherein the plurality of opening areas are respectively configured to have a same area.

9. The MIM capacitor of claim 1, wherein each of the plurality of lower electrodes is configured to have one of a rectangular shape and a stripe shape.

10. The MIM capacitor of claim 5, wherein the barrier metal, the dielectric layer, and the upper electrode are sequentially disposed on the first inter metal dielectric layer.

11. The MIM capacitor of claim 5, wherein the barrier metal of a first lower electrode is disposed to be connected to an adjacent barrier metal of a second lower electrode.

12. The MIM capacitor of claim 5, wherein the dielectric layer is disposed in direct contact with a top surface of the barrier metal.

13. A metal-insulator-metal (MIM) capacitor manufacturing method, the method comprising:
forming a first inter metal dielectric layer on a substrate;
forming a plurality of lower electrodes on the first inter metal dielectric layer;
forming a dielectric layer to cover a top surface and side surfaces of each of the plurality of lower electrodes; and
forming an upper electrode on the dielectric layer.

14. The method of claim 13, wherein each of the plurality of lower electrodes comprise a barrier metal, a metal layer, and a cap metal.

15. The method of claim 14, wherein the dielectric layer covers side surfaces of the barrier metal, the metal layer, and the cap metal.

16. The method of claim 13, wherein the plurality of lower electrodes are connected to each other to form a network of electrodes.

17. The method of claim 13,
wherein the plurality of lower electrodes comprise a barrier metal, a metal layer, and a cap metal, and
wherein the barrier metal of one of the plurality of lower electrodes is formed to be spaced from the barrier metal of an adjacent lower electrode of the one of the plurality of lower electrodes.

18. The method of claim 13, further comprising:
forming a plurality of first vias in the first inter metal dielectric layer;
forming a second inter metal dielectric layer on the upper electrode;
forming a plurality of second vias in the second inter metal dielectric layer; and
forming a metal wiring connected to the plurality of second vias,
wherein the plurality of first vias are connected to the plurality of lower electrodes.

19. A metal-insulator-metal (MIM) capacitor, comprising:
a first inter metal dielectric layer;
a barrier metal, disposed on the first inter metal dielectric layer;
a plurality of lower electrodes, disposed on the barrier metal;
a plurality of open areas respectively disposed between each of the plurality of lower electrodes;
a dielectric layer, disposed directly on the barrier metal, and further disposed on respective side surfaces and top surfaces of the plurality of lower electrodes; and
an upper electrode, disposed on the dielectric layer.

20. The MIM capacitor of claim 19, further comprising a second inter metal dielectric layer disposed on the upper electrode.
